(19) United States
(12) Patent Application Publication
(10) Pub. No.: US 2026/0206182 A1
(43) Pub. Date: Jul. 16, 2026

(54) Flow Divider For Liquid Flow Channel

(71) Applicant: Xiao Zeng, Zhuhai City (CN)

(72) Inventors: Xiao Zeng, Zhuhai City (CN); Yun Zeng, Zhuhai City (CN); JianFen Zhang, Zhuhai City (CN)

(21) Appl. No.: 19/020,008

(22) Filed: Jan. 14, 2025

(51) Int. Cl. H05K 7/20

(52) U.S. Cl. CPC H05K 7/20272; H05K 7/20772

(57) ABSTRACT

A flow divider for liquid flow channel, comprising a flow divider, a special-shaped flat tube, and a solid copper plate, wherein both ends of the flow divider are respectively provided with a water inlet and outlet; the special-shaped flat tube is welded on the flow divider to form a divider channel customized according to the number of memory bar storage modules, thereby realizing a reliable fluid circuit; the solid copper plate is welded to the special-shaped flat tube to form an integrated heat dissipation module, thereby achieving overall heat dissipation. The invention belongs to the technical field of flow dividers, and in particular to a flow divider for liquid flow channel.

### TECHNICAL FIELD

The invention belongs to the technical field of flow dividers, and in particular to a flow divider for liquid flow channel.

### BACKGROUND ART

As the performance of electronic devices continues to improve, the power of components such as server memory bars is also increasing, and traditional heat dissipation methods can no longer meet their heat dissipation needs. In liquid cooling modules, the flow divider is a key component, and its performance and reliability directly affect the effect of the entire cooling system.

However, existing flow dividers have many problems. For example, it is difficult to balance assembly convenience and heat dissipation performance in a small space; they cannot effectively cope with the heat dissipation challenges of high-power parts during use; they are prone to uneven heat dissipation and local overheating, which results in a high risk of damage to the liquid cooling module during use.

In addition, the processing technology of traditional flow dividers is complex, the production cost is high, and the production efficiency is low, which makes it difficult to adapt to the needs of large-scale mass production. At the same time, when facing heat sinks with different structures, there is a lack of adaptive structural design and the heat dissipation efficiency cannot be fully exerted. These problems seriously restrict the further development and application of liquid cooling technology in the field of electronic equipment.

### SUMMARY OF THE INVENTION

In view of the above situation, in order to overcome the defects of the prior art, the invention provides a flow divider for liquid flow channel, which effectively solves the problems of poor heat dissipation in a narrow installation space and insufficient structural adaptability.

In order to achieve the above function, the invention adopts the following technical solutions: a flow divider for liquid flow channel, comprising a flow divider, a special-shaped flat tube, and a solid copper plate, wherein both ends of the flow divider are respectively provided with a water inlet and outlet; the special-shaped flat tube is welded on the flow divider to form a divider channel customized according to the number of memory bar storage modules, thereby realizing a reliable fluid circuit; the solid copper plate is welded to the special-shaped flat tube to form an integrated heat dissipation module, thereby achieving overall heat dissipation.

Preferably, the special-shaped flat tube is a copper tube, and it is formed by bending and flattening a copper tube.

Preferably, the solid copper plate is installed above the special-shaped flat tube or installed above and below it simultaneously; the solid copper plate located above the special-shaped flat tube is embedded in the special-shaped flat tube.

Preferably, the special-shaped flat tube has different combination forms, and its length, width, and thickness can be designed and applied according to actual use.

Preferably, the solid copper plate is provided with an avoidance feature.

After adopting the above structure, the invention achieves the following beneficial effects:

While maintaining the original small space, it can meet the performance requirements of assembly and heat dissipation, which effectively solves the problem of uneven heat dissipation, improves heat dissipation efficiency, thereby better protecting high-power parts and reducing the risk of equipment failure caused by overheating.

The invention can be designed adaptively according to different heat sink structures to maintain the established heat dissipation capacity. Whether it is a multi-heat source arrangement or a longitudinal N+1 arrangement and other complex heat dissipation scenarios, it can achieve an optimized overall heat dissipation solution to meet the needs of all users. The adaptability of the scene heat dissipation design structure significantly improves the heat dissipation performance.

The invention adopts the method of bending and flattening a copper tube and then brazing it with the solid copper plate, and is cooperated with the required divider structure to form a stable fluid circuit, which increases the overall strength and enables it to adapt to the design and application of dividers of any structure, effectively solving the destructive risks of the liquid cooling module during use, and greatly improving the protection effect of the divider on high-power parts during application.

The manufacturing process of the invention is simple and can be realized by optimizing the existing conventional parts processing technology and welding technology, which simplifies the processing process and reduces the production cost. At the same time, it improves the welding quality level of the whole group of products, provides reliable technical support for mass production, helps to improve production efficiency and one-time qualified rate, and improves the reliability, rationality and economy of the processing technology.

The special-shaped flat tube of the invention can be freely combined, and its length, width, thickness and combination forms can be customized and applied according to the actual usage scenarios, which can meet diverse design and usage requirements, solve the reasonable assembly problems under conditions such as assembly in server memory bar heat dissipation modules and small spaces, and effectively improve the occurrence of many assembly problems such as installation difficulties and thickness interference in actual applications, thus achieving the purpose of full-scene installation.

### BRIEF DESCRIPTION OF THE DRAWINGS

FIG. 1 is a first overall structural diagram of the flow divider for liquid flow channel according to the invention.

FIG. 2 is a second overall structural diagram of the flow divider for liquid flow channel according to the invention.

FIG. 3 is a third overall structural diagram of the flow divider for liquid flow channel according to the invention.

FIG. 4 is a fourth overall structural diagram of the flow divider for liquid flow channel according to the invention.

FIG. 5 is a fifth overall structural diagram of the flow divider for liquid flow channel according to the invention.

FIG. 6 is a sixth overall structural diagram of the flow divider for liquid flow channel according to the invention.

FIG. 7 is a first diagram showing the flow divider for liquid flow channel in use according to the invention.

FIG. 8 is a second diagram showing the flow divider for liquid flow channel in use according to the invention.

FIG. 9 is a third diagram showing the flow divider for liquid flow channel in use according to the invention.

In the figures: 1 refers to the flow divider; 2 refers to the special-shaped flat tube; 3 refers to the solid copper plate; 4 refers to the avoidance feature; 5 refers to the water inlet and outlet.

### SPECIFIC EMBODIMENT OF THE INVENTION

The technical solutions in the embodiments of the invention will be clearly and completely described hereinafter with reference to the drawings in the embodiments of the invention. Obviously, the described embodiments are only a part of the embodiments of the invention, rather than all the embodiments. Based on the embodiments of the invention, all other embodiments obtained by those of ordinary skill in the art without creative efforts shall fall within the protection scope of the invention.

In the description of the invention, it needs to be understood that the orientation or positional relationship indicated by the terms “center”, “up”, “down”, “left”, “right”, “vertical”, “horizontal”, “inner”, “outer”, etc. are based on the orientation or positional relationship shown in the drawings, which are only for the convenience of describing the invention and simplifying the description, rather than indicating or implying that the device or element referred to must have a specific orientation, be constructed and operated in a specific orientation, and therefore cannot be understood as a limitation of the invention. In addition, the terms “first”, “second”, and “third” are only used for descriptive purposes, and cannot be understood as indicating or implying relative importance or implicitly indicating the number of indicated technical features.

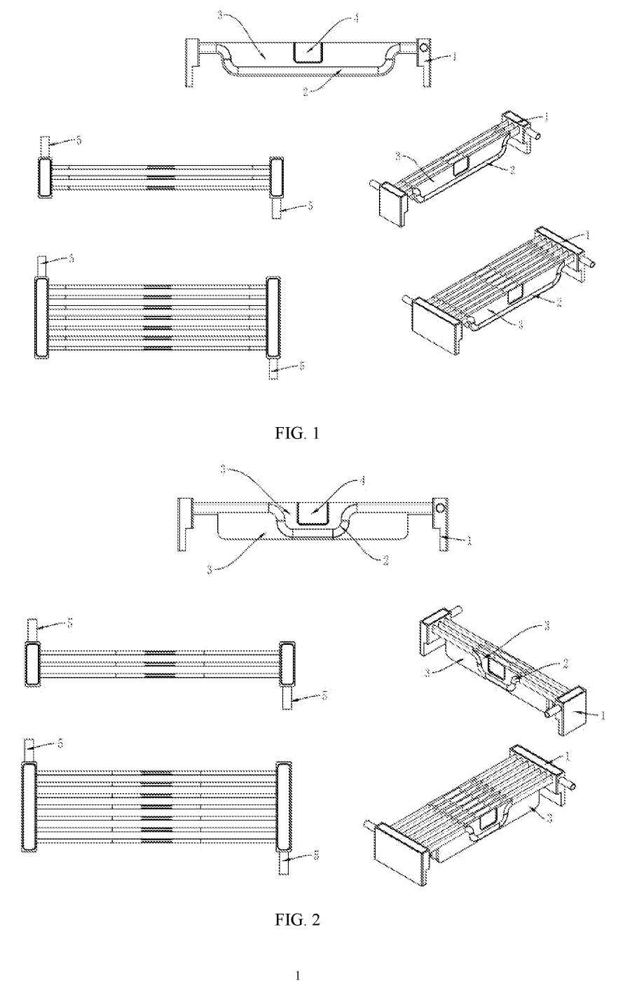

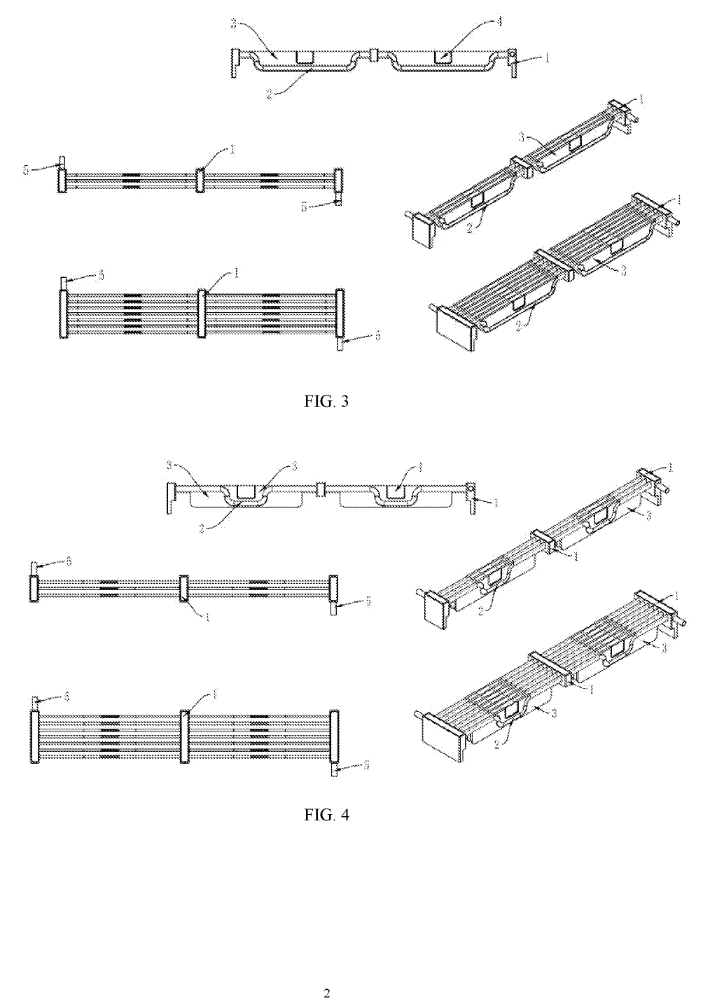

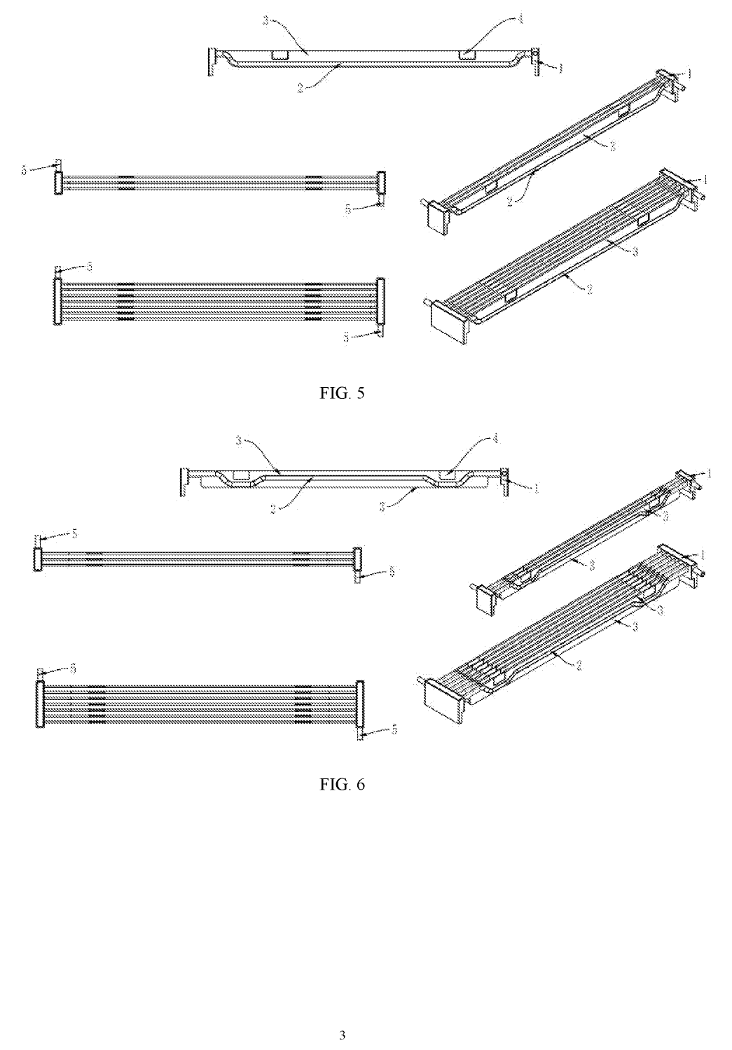

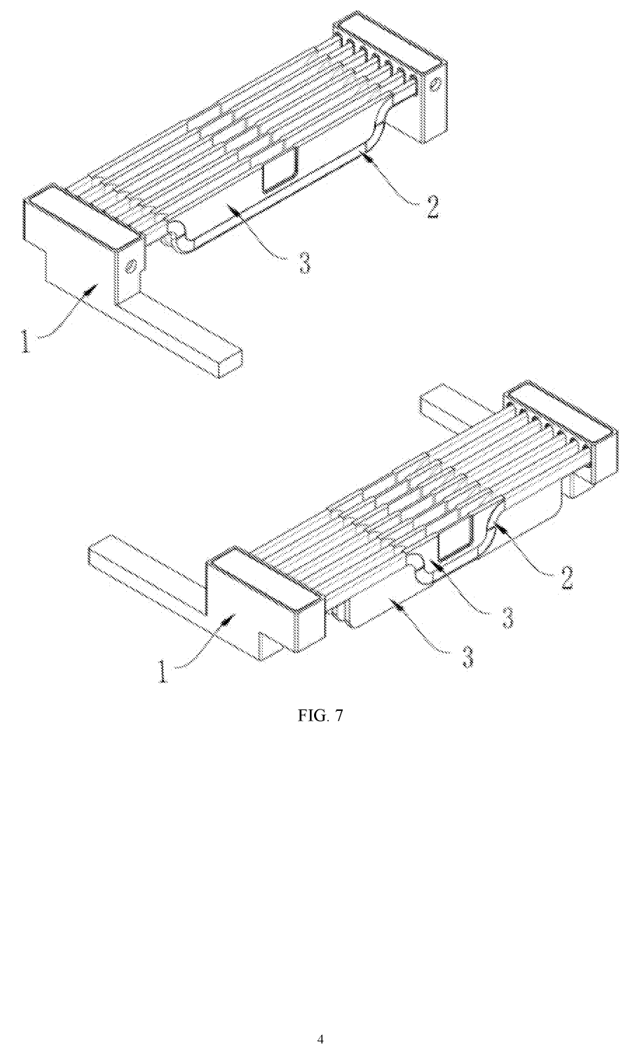

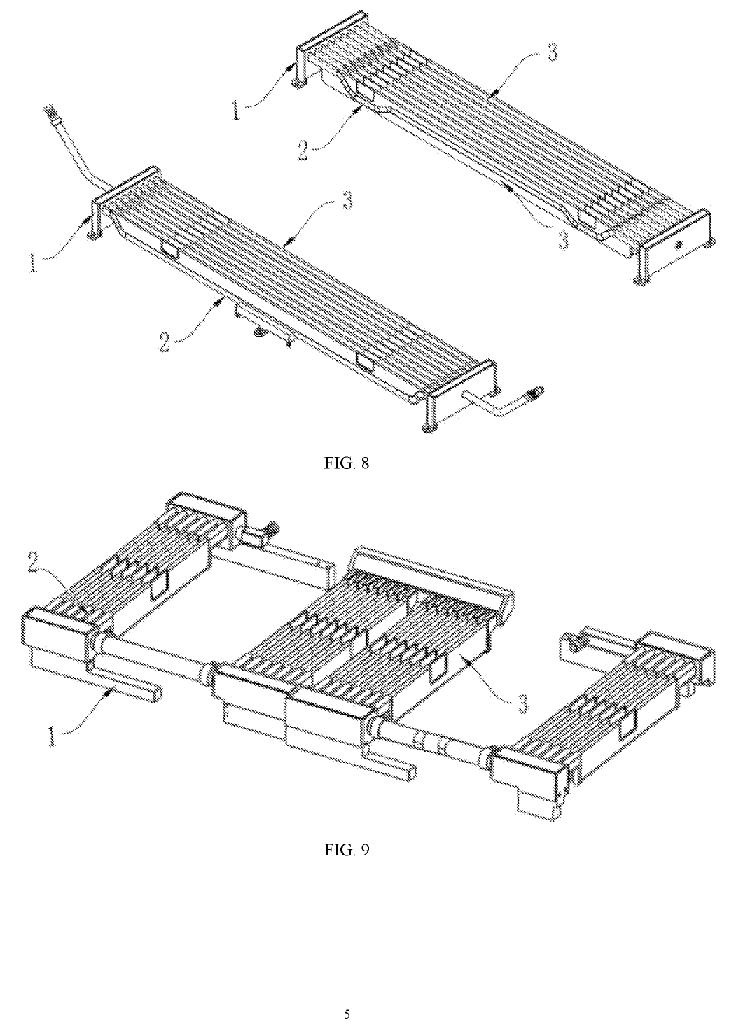

As shown in FIGS. 1-9, a flow divider for liquid flow channel according to the invention, comprising a flow divider 1, a special-shaped flat tube 2, and a solid copper plate 3, wherein both ends of the flow divider 1 are respectively provided with a water inlet and outlet 5; the special-shaped flat tube 2 is a copper tube, and it is formed by bending and flattening a copper tube, which increases the strength and saves space; the special-shaped flat tube 2 is welded on the flow divider 1 to form a divider channel customized according to the number of memory bar storage modules, thereby realizing a reliable fluid circuit; the solid copper plate 3 is welded to the special-shaped flat tube 2 to form an integrated heat dissipation module, thereby achieving overall heat dissipation; the solid copper plate 3 is provided with an avoidance feature 4 to facilitate assembly and avoid interference.

The special-shaped flat tube 2 has different combination forms, and its length, width, and thickness can be designed and applied according to actual use. The solid copper plate 3 is installed above the special-shaped flat tube 2 or installed above and below it simultaneously; the solid copper plate 3 located above the special-shaped flat tube 2 is embedded in the special-shaped flat tube 2. The solid copper plate 3 can absorb and store more heat, thereby enhancing the heat dissipation efficiency; at the same time, it can be used as a reinforcement structure to form a more stable whole, so that the heat dissipation module can better withstand various stresses during transportation, installation and use.

In specific use, a copper tube is firstly subjected to a profiling bending process to make its shape match the installation position, and then the bent copper tube is flattened according to the installation width size to form a special-shaped flat tube 2 as the base of the overall flat tube solution.

The solid copper plate 3 and the special-shaped flat tube 2 are connected by brazing to ensure a firm connection and good sealing, forming an integrated heat dissipation module, so that the coolant can circulate in the copper tube, and form a circulation loop via the water inlet and outlet 5 through the special-shaped flat tube 2 to achieve overall heat dissipation. The solid copper plate 3 cooperates to dissipate heat together, thereby achieving an efficient heat dissipation effect.

The design of the flow divider channel is customized according to the number of memory bar storage modules, and a suitable structure of the flow divider 1 is determined, such as combining the special-shaped flat tube 2 with the flow divider 1 structure by brazing to form a reliable fluid circuit to meet the heat dissipation requirements in different application scenarios.

Different matching methods can be set according to the heat dissipation area and installation design structure type of the heat dissipation component to be required, to achieve a derivative structure such as N+1 horizontal connection, or a combination of multiple heat source arrangement, longitudinal N+1 arrangement, etc., to meet the adaptability of the heat dissipation design structure in all scenarios. At the same time, it can still be adapted and installed with the flow divider 1 under the condition of extending the length of the flat tube body.

The invention and the embodiments thereof are described hereinabove, and this description is not restrictive. What is shown in the drawings is only one of the embodiments of the invention, and the actual structure is not limited thereto. All in all, structural methods and embodiments similar to the technical solution without deviating from the purpose of the invention made by those of ordinary skill in the art without creative design shall all fall within the protection scope of the invention.

1. A flow divider for liquid flow channel, comprising a flow divider, a special-shaped flat tube, and a solid copper plate, wherein both ends of the flow divider are respectively provided with a water inlet and outlet; the special-shaped flat tube is welded on the flow divider to form a divider channel customized according to the number of memory bar storage modules, thereby realizing a reliable fluid circuit; the solid copper plate is welded to the special-shaped flat tube to form an integrated heat dissipation module, thereby achieving overall heat dissipation.

2. The flow divider for liquid flow channel of claim 1, wherein the special-shaped flat tube is a copper tube, and it is formed by bending and flattening a copper tube.

3. The flow divider for liquid flow channel of claim 1, wherein the solid copper plate is installed above the special-shaped flat tube or installed above and below it simultaneously; the solid copper plate located above the special-shaped flat tube is embedded in the special-shaped flat tube.

4. The flow divider for liquid flow channel of claim 2, wherein the special-shaped flat tube has different combination forms, and its length, width, and thickness can be designed and applied according to actual use.

5. The flow divider for liquid flow channel of claim 1, wherein the solid copper plate is provided with an avoidance feature.
